(19) United States
(12) Patent Application Publication
(10) Pub. No.: US 2003/0190006 A1
(43) Pub. Date: Oct. 9, 2003

(54) Data recovery circuit

(76) Inventor: Hideo Nagano, Tokyo (JP)

Correspondence Address: BURNS, DOANE, SWECKER & MATHIS, L.L.P., P.O. Box 1404, Alexandria, VA, 22313-1404, US

(21) Appl. No.: 10/268,724

(22) Filed: Oct. 11, 2002

(30) Foreign Application Priority Data
Apr. 9, 2002 (JP) 2002-106481

(51) Int. Cl. H03D 3/24

(52) U.S. Cl. 375/376

(57) ABSTRACT

A data recovery circuit includes a phase locked loop circuit that includes a phase comparator, a VCO, and a 1/N frequency divider. A sampling reference clock CLK0 multiplied in frequency with respect to an input clock CLK with a factor of 7/4 is generated. Data that corresponds to three periods of the sampling reference clock CLK0 are held in a shift register by taking four bits as the unit. On the other hand, bits output as parallel data from data in the shift register are determined based on a count in a counter that counts seven periods of the sampling reference clock CLK0.

### BACKGROUND OF THE INVENTION

1) Field of the Invention

The present invention relates to a data recovery circuit that detects a head bit of a packet of data oversampled on the data reception side in a data transmission system having a plurality of data transmission channels.

2) Description of the Related Art

A data transmission form includes parallel data transmission in which a plurality of bits are transferred by using a large number of channels simultaneously, and serial data transmission in which data is transmitted bit after bit on a single channel. When transmitting data of the same quantity, the parallel data transmission is faster in transfer speed than the serial transmission. However, a large number of channels are used simultaneously, and thereby the number of signal lines is increased. As the speed increases, it becomes difficult to synchronize bits transmitted on separate channels. On the other hand, the serial data transmission is slower in transfer speed than the parallel transmission. However, the serial data transmission has a feature that the maximum transmission distance is long. Especially in recent years, a differential transmission system such as a low voltage differential signal (LVDS) having features of high speed, low voltage and low noise transmission is widely spread in monitors and the like having a digital interface.

A conventional serial data transmission system will now be explained with reference to a block diagram of FIG. 4 and a time chart of FIG. 5. FIG. 4 is the block diagram that shows a configuration of the conventional serial data transmission system between different devices. The conventional serial data transmission system encodes 7-bit data Data <6:0> in an encoder & serializer 61 included in a transmission side device 60, converts parallel data to serial data in synchronism with a clock, and transmits the converted serial data and the clock. The transmitted serial data and the clock arrive at a reception side device 62 via transmission lines 65, respectively. A terminal resistor 66 is connected to each of the transmission lines 65 in order to prevent reflection. The reception side device 62 includes a serializer 63 and a decoder 64. The reception side device 62 converts serial data transmitted from the transmission side device 60 via the transmission line 65 to parallel data by using the clock, and outputs the parallel data.

In a high-speed serial data transmission, the transmission side device 60 transmits the serial data and the clock in synchronism. Until the serial data and the clock arrive at the reception side device 62 via the transmission line 65, however, skew occurs in the serial data and the clock. Therefore, the serializer 63 uses a data recovery circuit when receiving the serial data and converting the serial data to parallel data. The data recovery circuit executes oversampling in order to determine data, i.e., samples one bit of received serial data a plurality of times, and obtains an optimum solution. Supposing, for example, that the transmission side device 60 conducts serial transmission of data by taking a 7-bit packet as the unit and oversampling five times per bit, thirty-five sampling edges per packet cycle are needed. Typically in such a data recovery circuit, therefore, a large number of sampling edges as explained above are often generated by using a voltage controlled oscillator (VCO) of a phase locked loop (PLL) circuit.

For example, the VCO generates a sampling reference clock multiplied in frequency with respect to the clock signal CLK synchronized to a packet cycle that is input from the transmission side device 60. The VCO also generates TAP clocks shifted in phase of the sampling reference clock multiplied in frequency, little by little so as to correspond to the number of times of oversampling. By using the sampling reference clock and the TAP clock, the oversampling is executed.

In the time chart of FIG. 5, a signal obtained by multiplying in frequency the input clock CLK by a factor of 7/4 received by the reception side device 62 is used as a sampling reference clock CLK0. If oversampling is conducted five times per bit, 19 TAP clocks (not shown) shifted in phase by (one period of the reference clock)/20 from each other is used for the reference clock CLK0.

Input data Din of the serializer 63 is oversampled by the TAP clocks generated by the VCO in one period of reference clock CLK0 of sampling. Sampling data are received in the order of Sa, Sb, Sc and Sd. In addition, phase adjustment is conducted. Sampling data Da, Db, Dc and Dd after the phase adjustment are output.

In such a conventional data recovery circuit, however, as the sampling reference clock for data recovery, not the clock CLK synchronized to the packet cycle transmitted from the transmission side device 60, but the clock CLK0 multiplied in frequency with respect to the clock CLK is used. Therefore, it cannot be determined where the head bit of recovered data taking a packet as the unit is located. In the conventional art, therefore, data that represents a break between packets is transmitted intentionally when transmitting data in the transmission side device 60. This results in a problem that the reception side device 62 must have a dedicated circuit in order to recognize the data that represents a break between packets.

### SUMMARY OF THE INVENTION

It is an object of this invention to provide a data recovery circuit of fast serial data capable of detecting a head bit of received serial data without transmitting data that represents a break between packets and without using a dedicated circuit.

The data recovery circuit according to this invention comprises a phase locked loop unit that generates a reference clock multiplied in frequency with respect to an input clock signal and TAP clocks that differ in phase from the reference clock based on the input clock signal, and an oversampling unit that conducts sampling on one bit of serial data a plurality of times by using the TAP clocks, obtains an optimum solution and outputs the optimum solution as data of a plurality of bits in synchronism with the reference clock. The data recovery circuit also comprises a head bit detection unit that generates a signal having a predetermined period corresponding to a plurality of periods of the clock signal and detects a head bit of the serial data from data of the plurality of bits output from the oversampling section.

These and other objects, features and advantages of the present invention are specifically set forth in or will become apparent from the following detailed descriptions of the invention when read in conjunction with the accompanying drawings.

### BRIEF DESCRIPTION OF THE DRAWINGS

FIG. 1 is a block diagram showing the data recovery circuit in an embodiment of the present invention,

FIG. 2 is a block diagram showing a head bit determination section of the data recovery circuit in the embodiment,

FIG. 3 is a time chart of the data recovery circuit in the embodiment,

FIG. 4 is a block diagram that shows the configuration of the serial transmission system of the conventional art, and

FIG. 5 is a time chart of the serial transmission system of the conventional art.

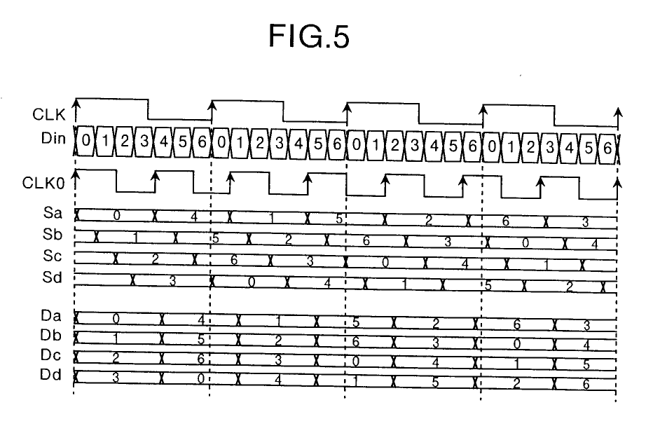

### DETAILED DESCRIPTION

Hereafter, an embodiment of the data recovery circuit according to the present invention will be explained with reference to the accompanying drawings.

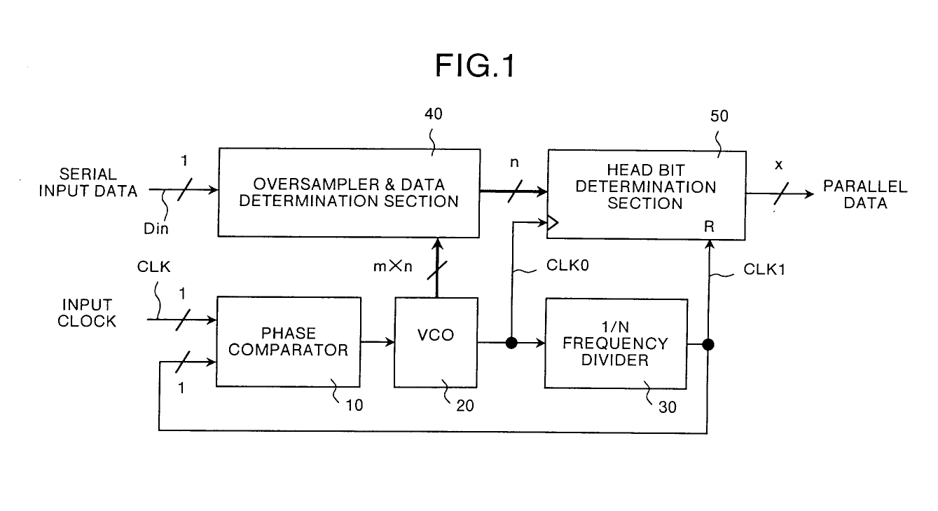

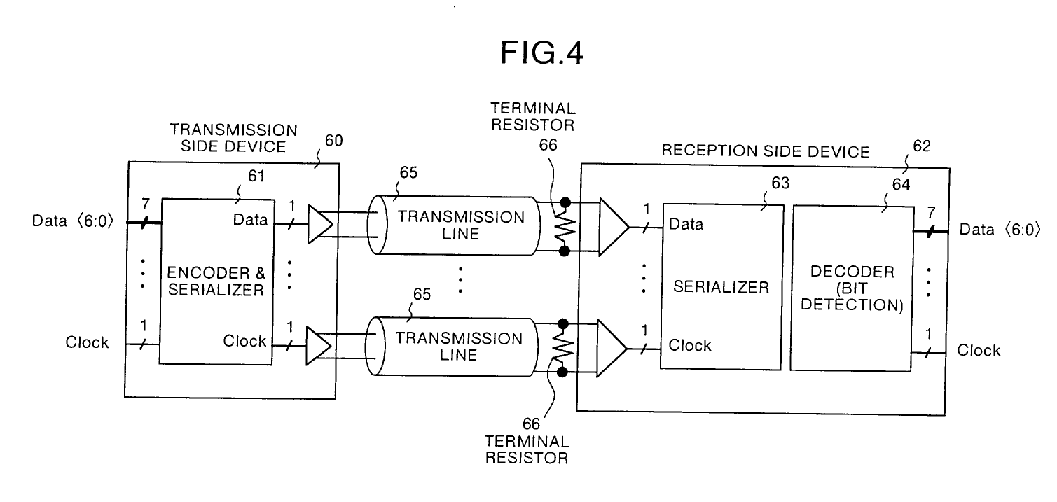

FIG. 1 is the block diagram that shows the configuration of the data recovery circuit of the embodiment. In the explanation of the embodiment, it is supposed that a clock obtained by multiplying in frequency the input clock CLK by a factor of 7/4 is used as the reference clock CLK0 of sampling in order to convert 7-bit serial data transmitted from the transmission side device of the conventional serial transmission system shown in FIG. 4 to parallel data, and the number of TAP clocks used to execute oversampling is 20.

The data recovery circuit of the embodiment includes a phase comparator 10, a VCO 20, a 1/N frequency divider 30, an oversampler & data determination section 40 and a head bit determination section 50.

The phase comparator 10 compares a phase of the input clock CLK with a phase of a comparison clock CLK1 generated by the 1/N frequency divider 30, and outputs a phase difference component between the two clocks as a pulsed phase difference signal.

The VCO 20 generates the sampling reference clock CLK0 multiplied in frequency by N with respect to the input clock CLK, and a plurality of TAP clocks in order to conduct oversampling. The TAP clocks are formed of (m×n) clocks, where m (m>1) is the number of times of sampling one bit of the serial input data Din and n (n≧1) is the number of bits of serial input data that are input in one period of the sampling reference clock CLK0. The TAP clocks are different in phase, but have the same period as that of reference clock CLK0. In other words, the TAP clocks are shifted in phase little by little so as to produce m×n different rising edges in one period of the reference clock CLK0. Here, the VCO 20 outputs the sampling reference clock CLK0 multiplied in frequency by a factor of 7/4 with respect to the input clock CLK, and 20 (5×4) TAP clocks required for oversampling.

The 1/N frequency divider 30 outputs the comparison clock CLK1 which is generated by dividing in frequency the sampling reference clock CLK0 generated by the VCO 20 by a factor of 1/N, to the phase comparator 10 and the head bit determination section 50. To be concrete, the 1/N frequency divider 30 outputs the comparison clock CLK1 having one period that is equal to seven periods of the sampling reference clock CLK0.

The oversampler & data determination section 40 receives the serial input data Din in the oversampling system using the TAP clocks, conducts phase adjustment for n bits (4 bits in this instance) of the serial input data Din input in one period of the sampling reference clock CLK0, and outputs 4-bit data Da to Dd to the head bit determination section 50.

The head bit determination section 50 stores the 4-bit data input from the oversampler & data determination section 40 every predetermined time corresponding to a plurality of periods of the input clock CLK, detects a head bit of the serial input data Din from the stored data, and outputs parallel data.

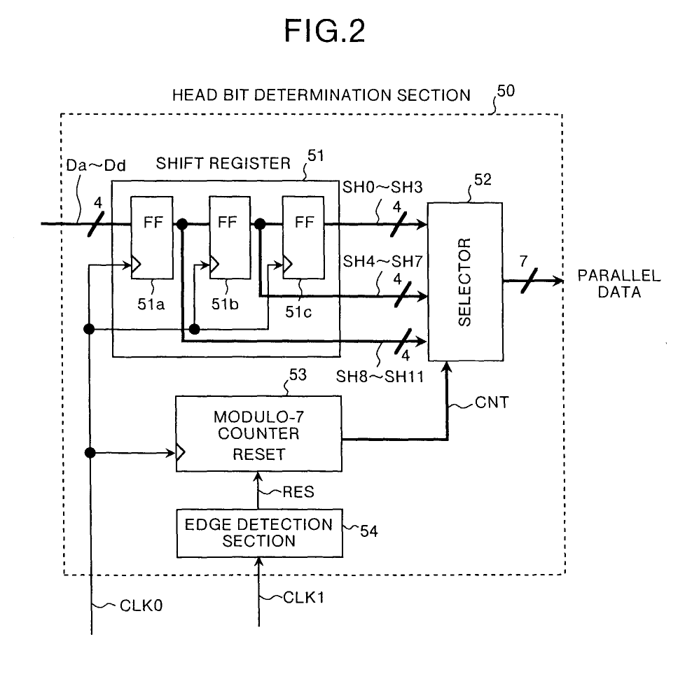

FIG. 2 is a block diagram that shows the configuration of the head bit determination section 50 shown in FIG. 1. The head bit determination section 50 includes a shift register 51, a selector 52, and a modulo-7 counter 53, and an edge detection section 54.

The shift register 51 is a 4-bit 3-stage shift register obtained by connecting 4-bit flip-flops 51a to 51c in triple cascade. Each of the flip-flops 51a to 51c functions to latch data at a rise of the sampling reference clock CLK0. The 4-bit flip-flops 51a to 51c output 12-bit register outputs SH0 to SH11 latched in the 4-bit flip-flops to the selector 52.

The edge detection section 54 detects a rise of the comparison clock CLK1 generated by the 1/N frequency divider 30. Upon detecting a rise, the edge detection section 54 generates a reset signal RES being in an asserted state for one period of the sampling reference clock CLK0 and outputs the signal to the modulo-7 counter 53.

The modulo-7 counter 53 executes count up using the sampling reference clock CLK0 generated in the VCO 20. The modulo-7 counter 53 is reset by the reset signal RES output from the edge detection section 54, therefore, the count is returned to zero. A count CNT in the modulo-7 counter 53 is output to the selector 52.

The selector 52 selects 7 bits from the register outputs SH0 to SH11 on the basis of the count CNT in the modulo-7 counter 53, and outputs the 7 bits as parallel data.

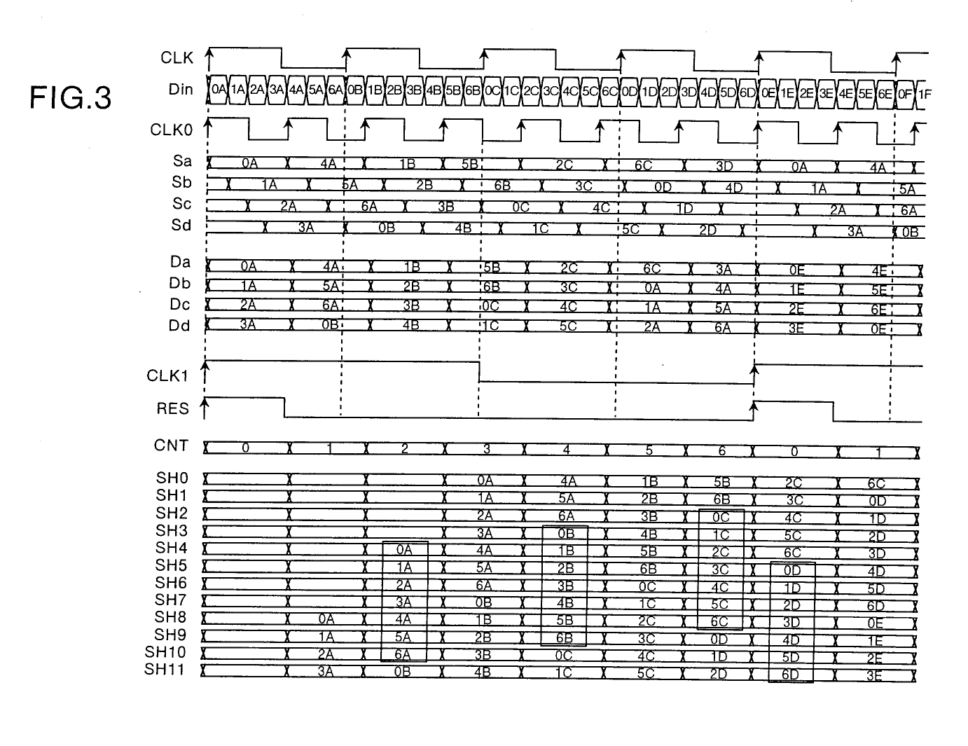

Operation of the data recovery circuit of the embodiment will now be explained with reference to the time chart of FIG. 3. The serial input data Din is input in the order of 0A to 6A, 0B to 6B, 0C to 6C, . . . in one period of the input clock CLK1. The VCO 20 generates the sampling reference clock CLK0 multiplied in frequency by a factor of 7/4 with respect to the input clock CLK, and the TAP clocks. The generated TAP clocks are output to the oversampler & data determination section 40. The sampling reference clock CLK0 is output to the 1/N frequency divider 30, and the modulo-7 counter 53 and the flip-flops 51a to 51c in the shift register 51 included in the head bit determination section 50.

The oversampler & data determination section 40 performs sampling on one bit of the serial input data Din five times by using the TAP clocks generated by the VCO 20. As for the serial input data Din, four bits are input in one period of the sampling reference clock. As shown in Sa to Sd, data sampled by the TAP clocks, which are generated by the VCO 20, are received every period of the sampling reference clock CLK0, and subject to phase adjustment by taking four bits as the unit. Sampling data Da to Dd of the oversampler & data determination section 40 are output to the flip-flop 51a in the shift register 51 of the head bit determination section 50. To be concrete, in synchronism with the sampling reference clock CLK0, the serial input data Din is output in the order of 0A, 4A, 1B . . . in the sampling data Da, 1A, 5A, 2B . . . in the sampling data Db, 2A, 6A, 3B . . . in the sampling data Dc, and 3A, 0B, 4B . . . in the sampling data Dd.

The sampling data Da to Dd output from the oversampler & data determination section 40 are latched into the 4-bit flip-flop 51a of the first stage in the shift register 51 of the head bit determination section 50 at a rise of the sampling reference clock CLK0. Register signals SH8 to SH11 output from the flip-flops 51a are latched into the flip-flops 51b. Register signals SH4 to SH7 output from the flip-flops 51b are latched into the flip-flops 51c. Data are thus shifted. Register outputs SH0 to SH11 output from the flip-flops 51a to 51c are output to the selector 52. To be concrete, first, at a rise of the sampling reference clock CLK0, 0A to 3A are latched into the flip-flops 51a. At the next rise of the sampling reference clock CLK0, the 0A to 3A are latched into the flip-flops 51b, and 4A to 6A and 0B are latched into the flip-flops 51a. At the next rise of the sampling reference clock CLK0, 0A to 3A are latched into the flip-flops 51c, 4A to 6A and 0B are latched into the flip-flops 51b, and 1B to 4B are latched into the flip-flops 51a. In this way, the sampling data Da to Dd output from the oversampler & data determination section 40 are taken into the shift register 51, and shifted. 0A to 6A and 0B to 4B are output on the register outputs SH0 to SH11.

On the other hand, the edge detection section 54 of the head bit determination section 50 detects a rise of the comparison clock CLK1 generated by the 1/N frequency divider 30 to be fed back to the phase comparator 10, generates the reset signal RES being in an asserted state for one period of the sampling reference clock CLK0, and resets the modulo-7 counter 53. In this instance, when the reset signal RES is a high level (“H”), the modulo-7 counter 53 is reset and the count CNT becomes 0. The modulo-7 counter 53 counts the sampling reference clocks CLK0 and outputs the count CNT to the selector 52.

On the basis of the count CNT of the modulo-7 counter 53, the selector 52 determines bits to be selected from 12 bits of register signals SH0 to SH11 output from the shift register 51. The serial input data Din is output on the register signals SH0 to SH11 output from the shift register 51 in a time series manner. The register signals SH0 to SH11 change by taking four bits as the unit in synchronism with the sampling reference clocks CLK0. While the modulo-7 counter 53 is counting from 0 to 6, therefore, packet data of the serial input data Din is output on the register signals SH0 to SH11 according to the count. In this instance, when the count CNT of the modulo-7 counter 53 is 2, 0A to 6A are output on the register signals SH4 to SH10 of the shift register 51. When the count CNT is 4, 0B to 6B are output on the register signals SH3 to SH9. When the count CNT is 6, 0C to 6C are output on the register signals SH2 to SH8. When the count CNT is 0 or 1, 0D to 6D are output on the register signals SH5 to SH11 or SH1 to SH8 of the shift register 51. In other words, by previously determining selected bits of register outputs in association with the count CNT, 7-bit parallel data is output.

Thus, in this embodiment, the phase comparator 10, the VCO 20, and the 1/N frequency divider 30 form the PLL circuit. The sampling reference clock CLK0 is generated by multiplying the frequency of the input clock CLK with a factor of 7/4. Data corresponding to three periods of the sampling reference clock CLK0 is held in the shift register 51 by taking four bits as the unit. On the other hand, bits output as parallel data from the data of the shift register 51 are determined by the count of the counter that counts seven periods of the sampling reference clock CLK0. Therefore, the head bit of the received serial data can be detected without transmitting data that represents a break between packets from the transmission side device and without using a dedicated circuit in the reception side device in order to detect the data that represents a break between packets.

An example in which the number of bits in converting the serial input data to parallel data is seven has been explained. However, the number of bits of data, the number of times of oversampling, and the sampling reference clock generated by multiplying the frequency of the input clock are not restrictive. The number of bits of the shift register 51 is the number of bits of the serial data input in one period of the sampling reference clock. The counter is reset every number of sampling reference clocks in a period of the comparison clock output from the 1/N frequency divider. Within the period, the output of the shift register 51 may be selected according to the count of the counter.

According to the data recovery circuit of the invention, a plurality of clocks required when converting serial input data to parallel data is generated by the PLL section. One of the generated clocks is used as a reference clock. Data obtained by oversampling serial input data by a plurality of clocks is stored as data of a plurality of bits every reference clock. Every predetermined time corresponding to a plurality of periods of an input clock signal supplied from the outside, a head bit of the serial data is detected. Therefore, the head bit of the received serial data can be detected without transmitting data that represents a break between packets from the transmission side device and without using a dedicated logic in the reception side device in order to detect the data that represents a break between packets.

Furthermore, the data of a plurality of bits output from the oversampling section is held. A fixed period is generated by counting a reference clock. A head bit is detected from the held data of a plurality of bits by using a count in the period. Parallel data is then output. Therefore, the head bit of the received serial data can be detected without transmitting data that represents a break between packets from the transmission side device and without using a dedicated logic in the reception side device in order to detect the data that represents a break between packets.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A data recovery circuit comprising:
a phase locked loop unit that generates a reference clock multiplied in frequency with respect to an input clock signal, and TAP clocks that differ in phase from the reference clock, based on the input clock signal;
an oversampling unit that conducts sampling on one bit of serial data a plurality of times by using the TAP clocks, obtains an optimum solution, and outputs the optimum solution as data of a plurality of bits in synchronism with the reference clock; and
a head bit detection unit that generates a signal having a predetermined period corresponding to a plurality of periods of the clock signal and detects a head bit of the serial data from data of the plurality of bits output from the oversampling section.

2. The data recovery circuit according to claim 1, wherein the head bit detection unit comprises:
a counter that counts pulses of the reference clock;
a register that latches the data of the plurality of bits output from the oversampling unit for a predetermined time by using the reference clock;
a decoder that determines bit order from the data latched in the register according to a count in the counter; and
a selector that outputs parallel data in order beginning with the head bit by using an output of the decoder.

3. The data recovery circuit according to claim 2, wherein the register is a shift register that shifts the data of the plurality of bits by a predetermined period.

4. The data recovery circuit according to claim 2, wherein the counter periodically resets a count using a reset signal that corresponds to one period of a reference clock, the reset signal being generated from a clock obtained by dividing in frequency the reference clock.

5. The data recovery circuit according to claim 2, wherein the selector selects a plurality of bits from the data latched into the register based on the count and outputs parallel data.

6. The data recovery circuit according to claim 1, wherein the TAP clock is formed of a plurality of clocks corresponding to a result of multiplying a number of times of sampling one bit of the serial data by a number of bits of serial data input in one period of the reference clock.

7. The data recovery circuit according to claim 6, wherein the plurality of clocks forming the TAP clock are shifted in phase to each other so as to produce a plurality of rising edges in the reference clock.

8. The data recovery circuit according to claim 1, wherein the oversampling unit conducts phase adjustment by a number of bits of the serial data input in one period of the reference clock to generate data of the plurality of bits.
